(19) United States
(12) Patent Application Publication
(10) Pub. No.: US 2006/0214177 A1
(43) Pub. Date: Sep. 28, 2006

(54) Cooling method and apparatus

(76) Inventor: Gareth JONES, Mid Glamorgan (GB)

Correspondence Address: JORDAN AND HAMBURG LLP, 122 EAST 42ND STREET, SUITE 4000, NEW YORK, NY, 10168, US

(21) Appl. No.: 10/565,424

(22) PCT Filed: Jul. 15, 2004
(86) PCT No.: PCT/GB04/03095

§ 371 Date: Mar. 29, 2006

(30) Foreign Application Priority Data
Jul. 17, 2003 (GB) 0316832.5

(51) Int. Cl. H01L 33/00

(52) U.S. Cl. 257/99; 257/712; 438/125; 257/E33.075

(57) ABSTRACT

A method and apparatus for cooling an electronic component, such as an optoelectronic device, is described. The method involves arranging a porous material to be able to receive heat from the electronic component and removing heat from the porous material as a result of vaporization of a coolant delivered to the porous material. In this manner, a temperature gradient is generated that causes heat to flow from the electronic device to the porous material, resulting in the electronic device being cooled.

### BACKGROUND OF THE INVENTION

This invention relates to a method of cooling an electronic component and an apparatus for performing such a method. The invention has particular, but not exclusive, application to the cooling of optoelectronic devices, such as for example, high brightness light emitting diodes and semiconductor lasers.

It is desirable to cool electronic components during their operation. Cooling can increase efficiency, can increase the maximum practically achievable output, for example power output, of an electronic component, and/or can increase the lifetime under operating conditions of the component. Many electronic components are mounted on heat sinks in order to cool the component during use. Such heat sinks generally rely on cooling of the component by means of heat passing from the component into the heat sink and then from the heat sink to the surroundings. In some applications, the cooling effect is increased by means of passing air over the heat sink by means of a fan. Other more sophisticated cooling systems have been proposed that employ conventional refrigeration techniques, for example, employing a refrigeration loop including circulated refrigerant, a condenser and/or an expansion valve.

### BRIEF SUMMARY OF THE INVENTION

The present invention aims to provide an improved cooling method and apparatus for cooling an electronic component during operation of the component.

According to the present invention there is provided a method of cooling an electronic component, the method including the following steps: I) providing an electronic component to be cooled, ii) arranging a porous material to be able to receive heat from the electronic component, and iii) removing heat from the porous material as a result of vaporization of a coolant from the porous material, whereby a temperature gradient is generated that causes heat to flow from the electronic component to the porous material, resulting in the electronic component being cooled.

Providing a porous material in such a way provides a relatively large surface area from which coolant may vaporize. Increasing the surface area will generally facilitate vaporization of more coolant and thus allow greater heat removal. For a given volume, the porous material has a much greater surface area, as compared to a solid component. Therefore, in comparison to a cooling system in which a conventional solid heat sink is cooled by means of vaporization of a coolant in contact with the heat sink, the rate of heat removal achievable by means of the use of the porous material of the present invention is greater.

It will be appreciated that heat may be removed from the porous material by means of coolant changing from a liquid to a vapor, or to a gas, by any of a variety of mechanisms. For example, the coolant may turn into the vapour or gaseous state by means of evaporation as a result of the addition of latent heat, resulting in heat being removed from the porous material. The coolant may turn into a gas by means of the coolant being caused to boil. As such it will be understood that the term “vaporization” includes within its meaning all such mechanisms of heat removal, including without limitation evaporation and boiling. Other related terms used herein such as “vaporize” should be construed similarly.

Preferably, the method includes a step of delivering coolant to the porous material. The coolant is advantageously delivered by spraying the coolant. The coolant may for example be delivered directly onto the surface of the porous material. The coolant and porous material advantageously have properties such that coolant on the surface of the porous material is absorbed by the porous material. The surface onto which coolant is delivered may be an external surface, namely a surface not wholly enclosed by the porous material or any other means (so that the surface is in free communication with the exterior of the porous material). Alternatively, the surface may be a surface on the interior of the porous material which is so wholly enclosed. The coolant may for example be injected into the interior of the porous material.

The rate of supply of coolant may be varied substantially periodically. The coolant may be delivered in pulses. The coolant may be delivered in pulses, wherein between pulses of relatively high flow rates of coolant there is still some, albeit at relatively low flow rates, supply of coolant to the porous material. There may for example be provided a means for applying a cooling pulse, in the form of a pulse of coolant, to said component. The pulses of coolant may be delivered at a predetermined time relative to an input energy pulse applied to the electronic component (for example, a pulse of electric power driving the electronic component). Preferably, each cooling pulse is applied prior to the application of a respective energy pulse.

The delivery of the coolant is preferably controlled by a control unit.

The control unit is advantageously arranged to control the rate of vaporization of the coolant. The delivery of the coolant may be controlled in dependence on a temperature dependent signal received by the control unit. The temperature dependent signal may for example be a measure of the temperature of a portion of the electronic component or a measure of the temperature of material in thermal contact with the component. The delivery of the coolant may be dependent on the way in which the electronic component is operated. For example, the delivery of the coolant may be controlled in dependence on the power driving the electronic component. In the case, where the coolant is supplied in pulses, the timing of the pulses may be controlled by the control unit. The timing of the pulses could for example be dependent on the timing of pulses of electric power to the electronic component. For example, the pulses of coolant may be synchronized with the pulses of power. The pulses of coolant and the power pulses in such a case need not be simultaneous.

For example, the cooling pulses may lag behind the power pulses. The power pulses may lag behind the cooling pulses. The control unit may thus be able to control the cooling rate and enhance the efficiency of cooling, whilst keeping the energy or coolant required to achieve such a cooling effect relatively low. The control unit is preferably arranged to control the rate of vaporization so that, after an initial time period, a steady state is reached at which the rate of heat removal is roughly equal to the rate of heat production generated by the operation of the device.

In the case where the coolant is supplied in pulses, the or each cooling pulse may comprise a burst of cooling gas, such as carbon dioxide (CO₂) or the like, which gas may be supplied from a suitable source, such as a pressurized gas cartridge or the like. The system preferably includes a control mechanism, for example forming a part of the above-mentioned control unit, for controlling the application of cooling pulses to the electronic component relative to the timing of the application of the energy pulses thereto. The control mechanism is preferably arranged to control the magnitude and/or the time of application of the cooling pulses. The control mechanism may be arranged to allow a controlled delay following the application of one energy pulse to the electric component before a cooling pulse is applied to the electric component. The control mechanism may also be arranged to allow a controlled delay between the application of a cooling pulse and the application of the next energy pulse to the electronic component. More than one cooling pulse may be applied to the electronic component between successive energy pulses applied to the component.

The electronic component may include an active part, which generates heat during operation. The active part may be mounted on one end of a heat sink, the opposite end of the heat sink being arranged to be cooled. According to a further aspect of the present invention, in which the provision of a porous material is optional, the heat sink may be cooled by means of cooling pulses being applied at or adjacent to said opposite end of the heat sink. This aspect of the invention has. particular application in relation to cooling electronic components which are driven with electric energy pulses. Thus, the application of a cooling pulse at some time before the active part of the component is pulsed causes heat to be transferred from the active part via the heat sink towards the cooled end of the heat sink (said opposite end of the heat sink). This has the effect of cooling the active part of the component, and setting up a temperature gradient within the apparatus that is essentially in the same direction as that which would occur when the active part is actually pulsed. When the electrical pulse is subsequently applied to the active part of the component, heat is generated, the removal of which is enhanced, by the above-mentioned effect of the application of the cooling pulse, because of the temperature gradient set up in the apparatus by the cooling pulse and because of the inevitable lower temperatures present in the active part and heat sink combination.

In accordance with this aspect of the present invention (concerning providing the coolant in pulses), there is also provided a cooling system for an electronic component (for example, an optoelectronic component), wherein the cooling system comprises means (for example, comprising a source of coolant and a controllable valve) for applying a cooling pulse to said component at a predetermined time relative to an input energy pulse applied to the electronic component (for example, a pulse of electric power driving the electronic component). The cooling pulse is, for example, applied by delivering a pulse of coolant directly to the component, to a part thereof or to a heat sink or other device (such as, for example, a porous material as described herein with reference to the present invention) in thermal communication with the component. The cooling system of this aspect of the present invention is able to introduce a cooling pulse of appropriate magnitude, the pulse being suitably timed with respect to the applied energy (or heating) pulse, so that the temperature rise in a region of the electronic component caused by the energy pulse is reduced (relative to components not employing or connected to the cooling system of this aspect of the invention) and the rate at which heat is transferred from said region (for example to a heat sink, which may be in the form of a porous material in accordance with other aspects of the invention herein described) is increased. It will be appreciated that any of the features described herein, especially those features described in relation to the supply of coolant in pulses, may be incorporated into this aspect of the invention. Furthermore, features described with reference to this aspect of the invention may be incorporated into other aspects of the invention described herein.

The coolant is preferably a gas at ambient temperature and pressure. The coolant could however be a liquid at ambient temperature and pressure, so that for vaporization, through evaporation for example, to take place at any significant rate the porous material would need to be at a temperature higher than ambient temperature. The coolant preferably has a freezing point below −30 degrees Celsius. The coolant is preferably delivered to the porous material at a temperature below ambient temperature. Ambient temperature may be defined as being room temperature. Ambient temperature may alternatively simply be defined as being 25 degrees Celsius. The coolant may be stored under pressure. The coolant is preferably a refrigerant. The coolant may comprise a HFC (ahydrofluorocarbon). The coolant may for example comprise either tetrafluoroethane and/or heptafluropropane. The boiling temperature of the coolant at atmospheric pressure is preferably less than 100 degrees Celsius and is preferably significantly below 100 degrees Celsius. For example, the boiling temperature may be lower than 50 degrees. Preferably the boiling temperature is below 30 degrees Celsius. It is preferred that the temperature of the porous material is able to be held at a temperature significantly lower than the normal operating temperature and more preferably at a temperature significantly lower than the uncooled operating temperature of the electronic component and of course at a temperature low enough to create a temperature gradient that causes heat to flow from the electronic component to the solid porous material. The boiling temperature of the coolant at atmospheric pressure may be less than 0 degrees Celsius. The boiling temperature may even be less than −20 degrees Celsius.

The porous material and the coolant may have properties such that the porous material is able to retain coolant. The coolant may for example be retained in the pores or free space formed within the porous material. The coolant need not therefore be supplied continuously. By contrast, if the porous material were replaced with a solid metal heat sink, the solid heat sink would not of course be able to absorb any liquid; rather, liquid would only be in contact with the external surface of the solid heat sink. Any excess liquid delivered to such a solid heat sink would simply be lost to the surroundings or collect in a pool as waste.

It will be understood that not all of the coolant supplied need be retained within the porous material and that the coolant is not retained indefinitely; rather, a large proportion, for example at least 10% (and more preferably at least 25%), of the coolant delivered is advantageously retained in the porous material as a liquid and preferably a large proportion, for example at least 50% (and more preferably at least 75%), of liquid coolant in the porous material leaves the porous material by means of vaporization, as opposed to leaking out as a liquid. The porous material preferably has an internal structure configured such, that on a local level (for example at a microscopic level), the orientation of the porous material does not significantly affect the effective performance of the cooling method. For example, the internal structure may be configured without any axial symmetry. Preferably, the method is so performed that on average during performance of the method at least 10% of the free space within the porous material is filled with retained liquid coolant. The retention of coolant within the porous material may be achieved by means of capillary or “wicking” action. The retention of coolant within the porous material may be achieved by means liquid surface tension forces interacting with the porous material. Because the porous material is able to retain coolant within its interior structure in accordance with this aspect of the invention, there is no need for any part of the exterior surface of the porous material to be in direct and continuous contact with a supply of coolant during performance of the method.

The coolant may be delivered to the porous material by means of a wicking action. For example, vaporization may occur primarily at upper and/or outer regions of the porous material and a reservoir of liquid coolant may be formed at an inner and/or lower portion of the porous material. Excess coolant delivered to the porous material may simply collect in the reservoir region in the porous material, provided that the reservoir region is not saturated with coolant. The wicking action may then draw liquid from the reservoir region at a rate dependent on the rate of vaporization. Thus the rate of consumption of the liquid may, at least to a limited extent, be self-regulated and the overall consumption of coolant may as a consequence be decreased by means of such a wicking action. Also, in the case where the coolant is supplied in pulses, using a porous material according to this aspect of the invention has an advantage, compared to the case where a solid metal heat sink is used, in that in order to keep a solid heat sink at a constant temperature coolant would need to be sprayed in a series of short precisely controlled pulses. According to this aspect of the invention, because the porous material retains coolant until it is wicked to the surface to vaporize, there can be a longer duration between pulses and furthermore there is no need for fine control of the pulsing of the coolant. A reservoir of coolant liquid may alternatively or additionally be formed in contact with, but externally in relation to, the porous material.

The porous material may comprise solid material that defines pores. The porous material may be formed of solid material that defines a multiplicity of interconnected pores. The pores are advantageously in fluid communication with adjacent pores. The porous material preferably has a porosity of between 4 and 4000 pores per centimeter, and more preferably between 4 and 40 pores per centimeter. The pores may be distributed throughout the material in a substantially random manner. Preferably, the porous material has pores with an average diameter of above 50 microns and preferably below 2000 microns. The pores may each be generally non-elongate in shape. For example, the pores may be very approximately spherical in shape. The average ratio of the long dimension of a pore to the short dimension may be less than 2. Preferably, the percentage of free space (by volume) in the space enveloped by a unit volume of the porous material is greater than 50%, and is more preferably greater than 50%. The percentage of free space may be less than 85%. Whilst the porous material could be in the form of a sintered metal, it is preferred that the porous material is in the form of a solid foam, for example a metal foam structure. Solid foams may be made to have a much higher porosity than sintered metals.

The porous material is preferably made of a material having a thermal conductivity that in at least one direction is higher than 50 Wm⁻¹K⁻¹, and more preferably higher than 100 Wm⁻¹K⁻¹. The porous material may be made from or comprise a metal material, for example copper. The porous material may be made from or comprise a non-metal material. The non-metal material may be carbon. The porous material may for example be made of or comprise graphite. The non-metal material may be silicon. The porous material may be made from a mixture of a metal and a non-metal, such as a mixture of Aluminum and Silicon. Advantageously, the composition of the porous material is chosen so that the thermal expansion properties of the porous material match those of the article against which the porous material is in use placed or secured. For example, in the case where the electronic component is in the form of a semiconductor to which the porous material is directly bonded, the porous material may be made from a mixture of Aluminum and Silicon, the mix being chosen such that the thermal expansion of the porous material matches that of the semiconductor material of the electronic component, thereby reducing the likelihood of undesirable stresses being generated by means of thermal expansion mismatches. The thermal conductivity of the porous material is advantageously improved by combining CVD Diamond (chemical vapour deposition diamond) within the structure of the porous material.

The porous material is preferably relatively rigid. For example, it is preferred that the porous material is able to support its own weight when saturated with coolant, without any noticeable deformation.

The porous material is preferably relatively flexible. For example, it is preferred that the porous material is able to expand and/or contract with the article against which the porous material is in use placed or secured. For example, in the case where the electronic component is in the form of a semiconductor to which the porous material is directly bonded, the porous material is preferably flexible enough that the porous material is able to accommodate the movement of the semiconductor material due to thermal expansion of that semiconductor material to an extent that reduces the likelihood of undesirable stresses being generated at the interface between the semiconductor and the porous material. Such undesirable stresses could for example cause a partial or total break at the interface between the porous material and the component (or heat sink, for example), which could lead to a reduction in thermal conductivity across the interface. In the case where the porous material is preferably relatively rigid, it is of course preferred that the rigidity of the porous material is only as great as is necessary to provide structural stability (so that the porous material retains its general shape and form throughout use), and preferably not so great as to detract from the advantages of having a certain amount of flexibility.

In the case where the electronic component is in the form of a semiconductor to which the porous material is directly bonded, the substrate of the semiconductor device may include pores, thereby enabling the coolant to get as close as possible to the active, heat generating part of the semiconductor device. This may, for example, be achieved by replacing a standard semiconductor substrate with a porous substrate.

The method of the present invention is preferably performed by means of delivering coolant to the porous material in an open-loop cooling system. It will be understood, that an open-loop cooling system differs from a closed-loop system in which coolant is circulated around a closed-loop. In accordance with the present invention, the porous material may be arranged to be vented directly to atmosphere. In that way, at least some of the coolant may be allowed to escape to the surroundings by means of vaporization. An advantage of using such an open loop system is that there is no need to provide a condenser arrangement for returning liquid coolant to the system. A closed coolant system could be provided however using the principles set out in this invention.

Preferably, the cooling method is performed such that there is no need for a step of pumping coolant through the porous material. The structure of the porous material may therefore be relatively simple.

The heat may be conducted from the electronic component to the porous material via a heat spreader. The electronic component may be mounted on a heat sink. The heat sink may be connected to such a heat spreader. It is preferred however that the electronic component be connected directly to the porous material. For example, the porous material may act as a heat sink. The porous material may be positioned directly adjacent to, and preferably in direct contact with, the heat generating part of the electronic component. In that case the heat can be removed extremely quickly allowing for the component to be driven at extremely high power levels for brief periods of time such as for example as is the case with a high power pulsed light emitting diode or laser diode component. In such a case, coolant is preferably delivered to a region of the porous material directly adjacent to the heat generating parts of the electronic component. In addition to positioning the porous material in direct contact with the heat generating part of the electronic device, in cases where the electronic device has a substrate, the substrate itself may be provided with pores to enable the coolant to get as close as possible to the heat generating part of the electronic device.

The electronic component may be a semiconductor device. The semiconductor device may have a porous substrate.

The electronic component may be a radiation emitting component, for example, arranged to emit electromagnetic radiation having a wavelength in the range of 200 nm to 10000 nm and more preferably in the range of 200 nm to 2000 nm. The electronic component may be a radiation emitting component arranged to emit visible light. The electronic component may be a high power device, for example a high power semiconductor device. In the context of this aspect of the present invention “high power” means an electric power high enough that the device needs to be actively cooled to allow effective or efficient operation, or at a power above normal operating powers thereby requiring cooling to enable the device to be driven at such a high power. If the device is a device for use in a telecommunications circuit, for example the device being a transistor, then high power may mean a power greater than 10 Watts. If the device is a light emitting device, such as a laser diode or a high powered light emitting diode, then high power may mean a power greater than 50 milli-Watts per light emitting device. The electronic component may form part of a larger circuit.

Preferably the method is so performed that at least a portion of the electronic component is cooled to below 100 degrees Celsius, and more preferably to below ambient temperature. The method may be so performed that at least a portion of the porous material is cooled to below ambient temperature, more preferably to below 0 degrees Celsius and yet more preferably to below −10 degrees Celsius.

The present invention is of particular application to the cooling of electronic components, wherein the part of the electronic component that is primarily responsible for generating heat during operation of the electronic component is relatively small in size, giving rise to relatively large thermal energy densities. The heat generating part of the component may for example have a volume of less than 1 cubic centimeter. The electronic component itself may example have a volume of less than 100 cubic centimeters.

The present invention also provides an apparatus for performing the method of the present invention. The invention provides an apparatus for cooling an electronic component, the apparatus including a porous material, a source of coolant, and a dispenser arranged to deliver, in use, coolant from the source of coolant into contact with the porous material, the apparatus being arranged such that in use the porous material is able to receive heat from an electronic component and such that in use such an electronic component is able to be cooled as a result of the vaporization of coolant from the porous material.

The apparatus may include a heat spreader for conducting heat from the electronic component to the porous material. The heat spreader may for example be in the form of a suitably shaped metal device arranged to transfer heat from a relatively small area on the electronic component to a relatively large area. The heat spreader may be made from or comprise copper metal. The heat spreader is preferably so configured and arranged that it does not impart a large thermal resistance to the path of heat transfer away from the electronic component.

The apparatus preferably includes a control unit. The control unit may for example comprise a micro-processor. The control unit is advantageously arranged to control, in use, the cooling of the component during use of the apparatus. The control unit may be arranged so as to prevent operation of the electronic component if a sensed temperature is above a threshold temperature. The sensed temperature may be representative for example of the temperature of a region of the electronic component. The sensed temperature may alternatively be dependent on the temperature of the electronic component. For example, the sensed temperature may be representative of the temperature of a heat spreader, or other device, connected to the electronic component.

The apparatus may be arranged simply to cool the electronic component continuously. Preferably, however the apparatus is arranged to maintain the temperature of a part of, or in the region of, the light source within a preset range. The control unit may be arranged to receive an input signal relating to a sensed temperature from a temperature sensor, such as for example comprising a thermocouple device. The temperature sensor is preferably positioned as close to the electronic component as possible. The control unit is preferably arranged to operate at least part of the apparatus in dependence on the input signal from the temperature sensor. For example, the apparatus could be operated in a feedback arrangement so as to control the temperature of the electronic component. The control unit may be arranged to maintain the sensed temperature to be at a temperature of less than 15 degrees Celsius, more preferably at a temperature of less than 0 degrees Celsius. The temperature may be maintained substantially within a range of between −40 and −10 and conveniently substantially within a range of between about −25 and about −10 degrees Celsius. The control unit may be arranged such that if the control unit detects that the temperature is outside the desired range then the control unit takes action that warns that the temperature is outside the desired range. Such action might be to operate a warning alarm, such as a visual or audio alarm, or may simple be to cease, at least temporarily, the operation of the electronic component.

The apparatus of the present invention may be supplied separately from the source of coolant. Thus, the present invention yet further provides an apparatus for cooling an electronic component, the apparatus including a porous material, and a dispenser arranged to be able to deliver, in use, coolant from a source of coolant into contact with the porous material, the apparatus being arranged such that in use the porous material is able to receive heat from an electronic component and such that in use such an electronic component is able to be cooled as a result of the vaporization of coolant from the porous material. The apparatus according to this aspect of the invention may of course further include a source of coolant.

The present invention yet further provides an electronic device including an electronic component arranged to be cooled by means of a method according to any aspect of the invention described herein or by means of an apparatus according to any aspect of the invention described herein.

According to the present invention, there is also provided a light emitting apparatus including a high intensity light emitting semiconductor component, wherein the semiconductor component is arranged to be cooled by means of a method according to any aspect of the invention described herein or by means of an apparatus according to any aspect of the invention described herein.

The present invention yet further provides a kit of parts including a porous material and a heat spreader, the kit of parts being arranged to be suitable for use in a method according to any aspect of the invention described herein or by means of an apparatus according to any aspect of the invention described herein.

It will be appreciated that the various aspects of the present invention described above are closely related and that therefore features described with reference to one aspect of the invention may readily be incorporated into another aspect of the invention. For example, the apparatus of the present invention may be arranged and configured so as to be suitable for performing the method of the present invention according to any aspect of the invention described herein. Thus, the apparatus may incorporate any of the features of the method according to any aspect of the invention described herein. Also the method may incorporate any of the features of the apparatus according to any aspect of the invention described herein. The method of the present invention may for example be performed by means of using the apparatus of the present invention. Thus, it will be understood, for example, that the porous material of the apparatus of the present invention may be in the form of a metal foam structure as described herein with reference to an aspect of the method of the invention.

### BRIEF DESCRIPTION OF THE DRAWINGS

Accompanying the specification are figures which assist in illustrating the embodiments of the invention, in which:

FIG. 1 shows a cooling system of a first embodiment for cooling a high power LED, the system including a metal foam structure;

FIG. 2 shows a sectional side view of the metal foam structure shown in FIG. 1;

FIG. 3 shows a graph of the temperature of a part of the cooling system against time;

FIG. 4 shows a sectional side view of a metal foam structure for use in a cooling system of a second embodiment;

FIG. 5a shows a sectional side view of a metal foam structure for use in a cooling system of a third embodiment; and

FIG. 5b is a plan view of the metal foam structure shown in FIG. 5a.

### DETAILED DESCRIPTION OF THE INVENTION

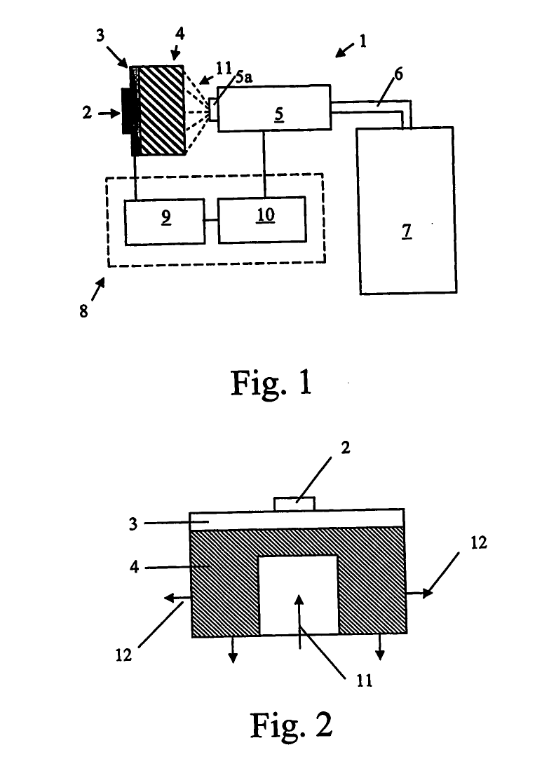

FIG. 1 shows a cooling system 1 attached to a high power high intensity light emitting semiconductor device in the form of a light emitting diode (LED) 2. The cooling system 1 comprises a heat spreader 3 in thermal relationship with the LED 2. The heat spreader 3 is attached to a metal foam structure 4, so that in use heat flows from the LED 2 via the heat spreader 3 to the metal foam structure 4. A fluid dispenser 5 is arranged to spray fluid onto the metal foam structure 4 by means of a micro-dispensing valve 5a. The fluid dispenser 5 is connected via a supply pipe 6 to a pressurized source 7 of refrigerant liquid. A control unit 8, comprising a temperature monitoring circuit 9 and a valve control circuit 10, controls operation of the cooling system 1. The temperature monitoring circuit 9 is arranged to sense and monitor the temperature of a portion of the heat spreader 3 by means of a thermocouple device (not shown). The valve control circuit 10 is arranged to control the dispensing of fluid by the fluid dispenser 5 in dependence on the temperature sensed by the temperature monitoring circuit 9. Whilst the control unit 8 is shown as comprising two separate units in FIG. 1, in reality the control unit 8 is provided as a single unit having a single microprocessor that controls operation of the system.

FIG. 2 shows, in cross section, the metal foam structure 4, heat spreader 3 and LED 2. The metal foam structure 4 is a copper foam having a porosity of about 60 ppi (the pores each having an average diameter of about 400 microns, there being 60 pores per linear inch, which is equivalent to about 1.3×10⁴ pores per cubic centi-metre. Such a metal foam structure may be in the form of the metal foam structure sold under the trade mark “Metpore” and available from Porvair Fuel Cells (part of a UK company Porvair PLC). The thermal conductivity of the metal foam structure 4 is 300 W/mK The refrigerant held in the pressurised source is HFC 134a(1,1,1,2 tetrafluoroethane). The boiling temperature of HFC 134a at ambient pressure is −26 degrees Celsius, that is the boiling temperature is significantly below 25 degrees Celsius, the ambient temperature (i.e. room temperature) of the environment in which the cooling system 1 is normally used. The refrigerant is held under pressure at ambient temperature (a pressure sufficient to cause the refrigerant to be in liquid form at ambient temperature).

The operation of the cooling system 1 will now be described. The LED 2 is driven by an electric power supply (not shown) that supplies pulses of electric power to the LED 2. The pulses of electric power, each lasting about 1 second, are supplied at a frequency of about 0.5 Hz. The temperature of the active part of the LED 2 is continually monitored by the temperature monitor circuit 9 indirectly by means of the measurement of the temperature of the heat spreader 3. If the monitored temperature exceeds a pre-set threshold temperature of −12 degrees Celsius the control unit 8 causes the valve control circuit 10 to operate the valve of the fluid dispenser 5. The valve causes a small jet 11 of fluid to be sprayed onto the metal foam structure 4 during a pulse lasting about 200 milliseconds, the fluid being provided from the pressurized source 7 of refrigerant. The cooling pulses are synchronized to end immediately before the start of each pulse of power (or to start about 800 milliseconds after the end of a pulse of power).

The refrigerant, as it is released, is subjected to a drop in pressure, expands and cools and also partially evaporates cooling the spray further. Owing to the extraction of heat from the refrigerant fluid by means of the latent heat of vaporization, the temperature of the fluid released from the valve is caused to drop to a temperature around or just below the boiling point of the liquid. The refrigerant fluid received by the metal foam structure 4 is therefore a mixture of gas and liquid having a temperature at below −26 degrees Celsius.

With reference to FIG. 2, the jet 11 of coolant is directed onto an external surface of the foam 4, albeit in a cavity formed in the metal foam 4. The metal foam structure 4 absorbs and retains liquid refrigerant owing to the wicking nature of the foam (due to capillary action and the like). The temperature of the metal foam structure 4 is thus lowered and the temperature of the refrigerant is raised as heat flows from the metal foam structure 4 to the refrigerant. A temperature gradient is therefore created between the LED 2 and the metal foam structure 4. As such heat flows from the LED 2 to the metal foam structure, via the heat spreader 3, thereby lowering the temperature of the LED 2.

The liquid refrigerant vaporizes at a rate largely dependent on the temperature of the metal foam structure 4. If the temperature of the metal foam structure 4 is above the boiling point of the refrigerant fluid (as is likely), the liquid will boil and vaporize rapidly. The vaporization of the liquid removes further heat from the metal foam structure 4 and thus further lowers the temperature of the LED 2. The arrows 12 leading away from the metal foam 4 in FIG. 2 show the regions at which most evaporation occurs. An important point to be made is that the temperature of the liquid cannot rise above −26 degrees Celsius. Once the liquid has warmed up to −26 degrees Celsius—further heat supplied by the LED is removed very quickly through vaporization of the liquid either through surface vaporization or boiling of the liquid within the bulk of the coolant. Since the coolant is a liquid the cooling action is highly efficient and the vaporized components are replenished quickly by further coolant through the “wicking” action.

The cooling system is an open loop system, in which refrigerant evaporates to atmosphere and is therefore lost. As such, refrigerant is consumed during operation of the apparatus.

Pulses of refrigerant are sprayed onto the metal foam structure 4 until the temperature monitored by the temperature monitoring circuit 9 drops to below the threshold temperature. In general the cooling pulses are timed to maintain a temperature efficiently during operation and therefore may be considerably shorter than the pulses of current to the LED. The cooling pulses are applied at the same frequency as the electric power pulses driving the LED 2, namely at 0.5 Hz, so that the cooling pulses and the electric power pulses are synchronized (see above), albeit with a constant time delay. During operation of the LED 2 and the cooling system 1, the monitored temperature may remain above the threshold temperature so that the cooling system 1 is continuously performing the cooling method.

During operation, an equilibrium may be reached at which the rate of heat removal (which is of course dependent on the rate of coolant vaporization) equals the rate of heat generated by the LED 2. If such an equilibrium is reached the temperature of the various parts of the apparatus remain substantially constant.

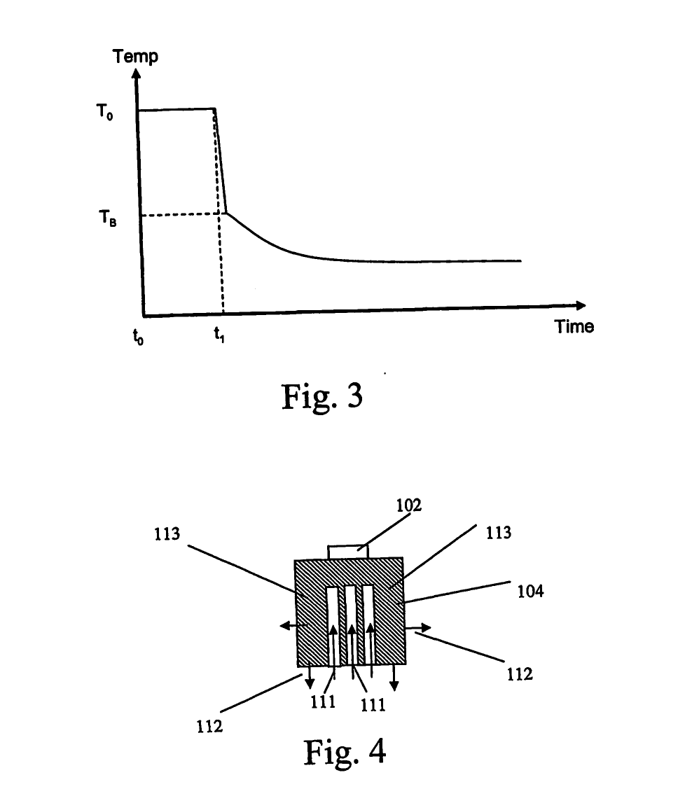

The graph shown in FIG. 3 illustrates schematically how the temperature of the system 1 varies with time during a single pulse of refrigerant fluid from start up of the cooling system 1 to illustrate the cooling mechanism employed. The vertical axis of the graph represents the temperature of the heat spreader and the horizontal axis represents time. At time t₀, the temperature of the heat spreader is at T₀. A pulse of coolant is sprayed onto the metal foam structure 4 at time t₁. The temperature of the metal foam structure 4 quickly drops to the temperature of the boiling temperature T_{B} of the refrigerant and, in turn, the temperature of the heat spreader 3 also quickly reaches temperature T_{B}. After time t₁ the temperature of the heat spreader 3 continues to drop as the temperature of the metal foam structure 4 drops due to vaporization of the refrigerant.

FIG. 4 shows the geometry of a metal foam structure according to a further embodiment of the invention, which is similar to that illustrated in FIG. 2. The differences between the cooling system of FIG. 4 and the cooling system illustrated by FIGS. 1 and 2 will now be described. The metal foam structure 104 is directly bonded to the semiconductor die of the LED, thereby dispensing with the heat spreader. Coolant is supplied (see arrows 111) to the interior of the metal foam 104 by means of three injection pipes (not shown) that seal over three bores 113 in the foam. The coolant is thus supplied at a region directly adjacent to the active, heat generating, part of the LED 102. Thus, in this case, the time lag between applying coolant and heat being removed from the LED 102 is relatively short, as a result of the close proximity between the semiconductor die of the LED 102 and the region to which coolant is delivered. This embodiment is very well suited to applications in which very short high power pulses are used. The evaporation of coolant gas from the metal foam 104 is represented by arrows 112. Another advantage of this embodiment is the smaller size of the foam improving the response time of the cooling system and reducing the coolant fluid consumption.

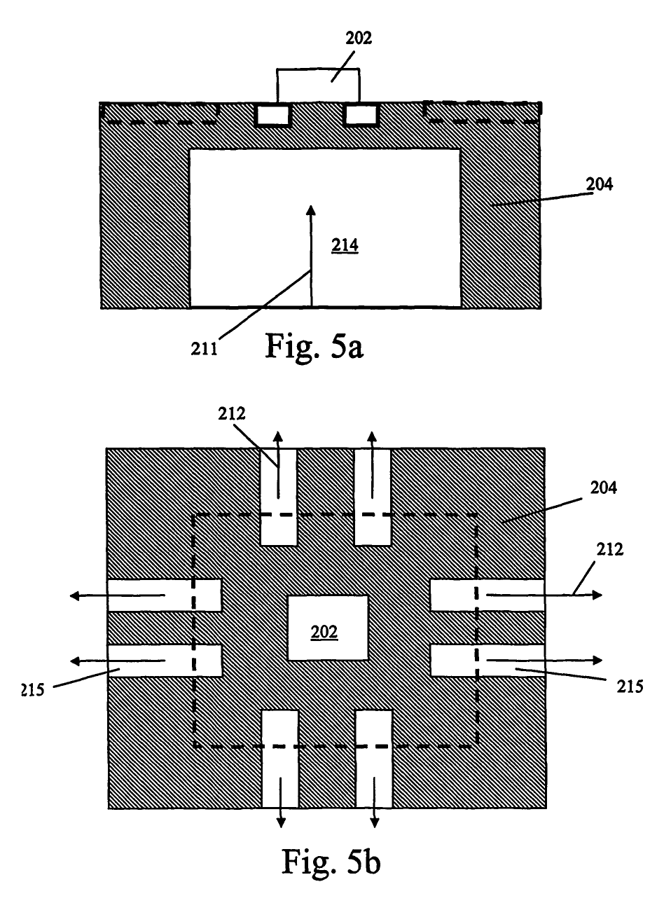

FIGS. 5a and 5b show the geometry of a metal foam structure 204 according to a yet further embodiment of the invention, which is similar to that illustrated in FIG. 4. Again there is no separate heat spreader and the foam 204 is connected directly to the LED 202. The geometry of the metal foam 204 is different from that of FIG. 4, in that a large central bore 214 is provided for receiving the delivery of sprayed coolant and eight smaller bores 215, radiating from the center (when viewed from above-see FIG. 5b) of the foam, are provided to assist vaporization of coolant from the foam 204. The smaller bores 215 effectively increase the external surface area of the foam, per unit volume of foam. Delivery of coolant to the foam is represented by arrow 211 and the evaporation of coolant gas from the metal foam 204 is represented by arrows 212. The particular size and shape of the foam and the bores within it is dependent on the die size and cooling requirements.

In a further variant of the invention in which the LED 202 includes a substrate, the substrate itself includes pores.

It will be appreciated that various modifications may be made to the above-described embodiment without departing from the spirit of the invention. For example, the electronic component may be any component that would benefit from being actively cooled. A number of modifications may be made to the cooling apparatus depending on the application of the cooling system. The shape, size and structure of the metal foam structure may be changed. The rate at which heat is transferred from the metal foam structure to the refrigerant in the metal foam structure will depend partly on the surface area of the metal foam structure in contact with the refrigerant, which may be changed by means of altering the geometry and/or structure, for example the porosity, of the metal foam structure.

A fan could be provided to force air past and over the metal foam structure thereby increasing the rate of vaporization of the coolant. The rate of cooling could then be controlled, by controlling the rate of vaporization of the fluid by means of controlling the flow rate of air by controlling the fan speed.

Also the characteristics of the wicking action may be varied, if desired, by altering the structure of the metal foam structure. For example, the size and number of the pores of the metal foam structure and the geometry of the metal structure forming the pores (for example the extent to which adjacent pores are connected) may be altered to change the wicking characteristics, and the liquid storage capacity. The efficiency of the cooling system, in terms of the maximum rate of cooling achievable with a given rate of supply of refrigerant, may depend on the wicking characteristics of the metal foam structure.

The length of cooling pulses may be altered to vary the rate of heat removal. Different frequencies and pulse lengths of the electric power supplied may of course be used (pulses of for example 100 to 200000 μs at frequencies of 0.1 to 10 Hz. The power pulses and cooling pulse could of course overlap.

The metal foam structure may be made from materials other than copper. For example, the material could be graphite, porous Silicon, a porous spray-formed mixture of Aluminum and Silicon, or any other high thermal conductivity material able to be formed as a solid foam or other porous structure. In the case where porous spray-formed Aluminum and Silicon mixture is used, the ratio of Aluminum to Silicon may be varied so as to provide a thermal expansion match to the electronic component (for example a semiconductor), so that the metal foam structure may be bonded directly to the electronic component without any great risk of a thermal expansion mismatch. Of course, if the metal foam has a relatively high compressibility (i.e. is relatively flexible) the need for a thermal expansion match is not as important, since expansion may be accommodated by mechanical compression or expansion of the foam structure.

The thermal conductivity of the metal foam structure may be improved by combining CVD Diamond within the metal foam structure.

The refrigerant may be replaced by any suitable HFC, such as for example 1,1,1,2,3,3,3-heptafluoropropane or by any other suitable coolant, including for example carbon dioxide gas.

The present invention may be embodied in other specific forms without departing from its spirit or essential characteristics. The described embodiments are to be considered in all respects only as illustrative and not as restrictive. The scope of the invention is, therefore, indicated by the appended claims and their combination in whole or in part rather than by the foregoing description. All changes that come within the meaning and range of equivalency of the claims are to be embraced within their scope.

1. A method of cooling an electronic component, the method comprising the following steps:
providing an electronic component to be cooled;
arranging a porous material to be able to receive heat from the electronic component; and
removing heat from the porous material as a result of vaporisation of a coolant from the porous material,
whereby a temperature gradient is generated that causes heat to flow from the electronic component to the porous material, resulting in the electronic component being cooled.

2. A method according to claim 1, wherein the method comprises a step of delivering the coolant directly onto the exterior surface of the porous material.

3. A method of claim 2, wherein the step of delivering the coolant is performed by spraying the coolant.

4. A method of claim 1, wherein the method comprises a step of delivering coolant into the interior of the porous material.

5. A method of claim 1, wherein delivery of the coolant is controlled by a control unit in dependence on a temperature dependent signal received by the control unit.

6. A method of claim 1, wherein delivery of the coolant is controlled by a control unit in dependence on the power driving the electronic component.

7. A method of claim 1, wherein the coolant is a gas at ambient temperature and pressure.

8. A method of claim 1, wherein the coolant is delivered at a temperature below ambient temperature.

9. A method of claim 1, wherein the coolant is stored under pressure.

10. A method of claim 1, wherein the porous material and the coolant have properties such that the porous material is able to retain coolant.

11. A method of claim 1, wherein the porous material has a porosity of between 4 and 40 pores per centimeter.

12. A method of claim 1, wherein the porous material comprises a solid foam.

13. A method of claim 1, wherein the porous material has a thermal conductivity that in at least one direction is higher than 50 Wm⁻¹K⁻¹.

14. (canceled)

15. A method of claim 1, wherein the electronic component is a semiconductor device.

16. (canceled)

17. A method of claim 1, wherein the electronic component is a radiation emitting component arranged to emit electromagnetic radiation having a wavelength in the range of 200 nm to 10000 nm.

18. A method of claim 1, wherein at least a portion of the electronic component is cooled to below ambient temperature.

19. An apparatus for cooling an electronic component, the apparatus comprising a porous material, a source of coolant, and a dispenser arranged to deliver, in use, coolant, from the source of coolant into contact with the porous material, the apparatus being arranged such that in use the porous material is able to receive heat from an electronic component and such that in use such an electronic component is able to be cooled as a result of the vaporisation of coolant from the porous material.

20. An apparatus according to claim 19, wherein the apparatus comprises a heat spreader for conducting heat from the electronic component to the porous material.

21. An apparatus according to claim 19, wherein the apparatus comprises a control unit for controlling the cooling of the component during use of the apparatus.

22. An apparatus according to claim 21, wherein the control unit is arranged so as to prevent operation of the electronic component if a sensed temperature is above a threshold temperature.

23. An apparatus for cooling an electronic component, the apparatus comprising a porous material, and a dispenser arranged to be able to deliver, in use, coolant, from a source of coolant into contact with the porous material, the apparatus being arranged such that in use the porous material is able to receive heat from an electronic component and such that in use such an electronic component is able to be cooled as a result of the vaporisation of coolant from the porous material.

24. An electronic device including an electronic component cooled by a method according to claim 1.

25. A light emitting apparatus including a high intensity light emitting semiconductor component, wherein the semiconductor component is cooled by a method of claim 1.

26. A kit of parts including a porous material and a heat spreader, the kit of parts being applied in a method of claim 1.

27. An electronic device including an electronic component cooled by an apparatus of claim 19.

28. A light emitting apparatus including a high intensity light emitting semiconductor component, wherein the semiconductor component is cooled by an apparatus of claim 19.

29. A kit of parts including a porous material and a heat spreader, the kit of parts being applied in an apparatus of claim 19.

30. An electronic device including an electronic component cooled by an apparatus of claim 23.

31. A light emitting apparatus including a high intensity light emitting semiconductor component, wherein the semiconductor component is cooled by by an apparatus of claim 23.

32. A kit of parts including a porous material and a heat spreader, the kit of parts being applied in an apparatus of claim 23.

33. The method of claim 1, wherein the coolant is delivered in pulses.
